(19) United States
(12) Patent Application Publication
(10) Pub. No.: US 2026/0287263 A1
(43) Pub. Date: Sep. 24, 2026

(54) PASSIVE COOLING APPARATUS FOR COOLING OF IMMERSION FLUID AND POWER CONVERSION EQUIPMENT INCLUDING A SHAPE-MEMORY ALLOY HEAT ENGINE AND RELATED SYSTEMS

(71) Applicant: Eaton Intelligent Power Limited, Dublin 4 (IE)

(72) Inventors: Avadhoot Kittur, Pune (IN); Donald Caulfield, Raleigh, NC (US)

(21) Appl. No.: 19/477,269

(22) PCT Filed: May 29, 2024
(86) PCT No.: PCT/IB2024/055223

§ 371 Date: Oct. 21, 2025

Related U.S. Application Data
(60) Provisional application No. 63/504,904, filed on May 30, 2023.

(51) Int. Cl. F28D 1/02; F03G 7/06

(52) U.S. Cl. CPC F28D 1/0233; F03G 7/06143

(57) ABSTRACT

A passive fluid cooling system is provided including an immersion cooling tank including a volume of fluid; and a shape memory alloy (SMA) heat engine, the SMA heat engine including a plurality of wheels and an SMA wire coupled to the plurality of wheels. A portion of the SMA wire is in contact with the volume of fluid and transitions from a relaxed state to a tightened state when a temperature of the volume of fluid exceeds a transformation temperature of the SMA wire. The tightening of the SMA wire causes the plurality of wheels to rotate and induce motion in the volume of fluid and causes the volume of fluid to decrease in temperature.

### CROSS-REFERENCE TO RELATED APPLICATION

The present application claims the benefit of and priority to U.S. Provisional Application No. 63/504,904, filed May 30, 2023, entitled Passive Cooling Apparatus for Cooling of Immersion Fluid and Power Conversion Equipment Including a Shape-Memory Alloy Heat Engine and Related Systems, the content of which is hereby incorporated herein in its entirety.

### FIELD

The present inventive concept relates generally to immersion fluid and, more particularly, to the cooling of immersion fluid.

### BACKGROUND

The most common method for cooling information technology (IT) equipment, for example, equipment in data centers, power conversion equipment and the like is forced air. Using air as the coolant generally requires, for example, fans, ductwork, heating ventilation and air conditioning (HVAC) systems etc., which may consume a lot of space and electricity and generally add a cost.

An alternative to using air to cool the equipment is immersion cooling, which is more energy and space efficient. Immersion cooling involves immersing system components in a fluid which, ideally, has a high coefficient of heat absorption and a low thermal resistance. Additionally, the process generally requires the use of fluids that will not damage the IT components or degrade system function. For safety reasons, these fluids need to be “dielectric,” meaning they do not conduct electricity. The dielectric fluids used for immersion cooling today generally fall into two categories: oils (synthetic, mineral, bio) and engineered fluids.

Methods of immersion cooling involve immersing components and/or equipment in a dielectric fluid. The heat generated by the IT components is absorbed by the fluid and then the fluid is pumped and circulated around inside an enclosure, chassis or tank to help remove the heat. The method entails further pumping of the hot oil/fluid to be cooled by a secondary air-to-liquid or liquid-to-liquid heat exchanger and pumping cooled oil/fluid back into the immersion bath. Some methods include an entirely enclosed IT chassis that contains the dielectric fluid and oftentimes less fluid is needed as a result. Some methods include an entirely enclosed IT tank/immersion tank. The tanks provide containment of the dielectric fluid and are typically designed to accommodate IT components that would otherwise be mounted in racks. Since the immersion tanks accommodate almost all types of IT components, there is no need to replace the immersion tank for an IT refresh. This makes the flexibility and cost highly appealing for immersion tank versus the chassis approach. Although immersion cooling is available, improvements are needed.

### SUMMARY

Some embodiments of the present inventive concept provide a passive fluid cooling system including an immersion cooling tank including a volume of fluid; and a shape memory alloy (SMA) heat engine, the SMA heat engine including a plurality of wheels and an SMA wire coupled to the plurality of wheels. A portion of the SMA wire is in contact with the volume of fluid and transitions from a relaxed state to a tightened state when a temperature of the volume of fluid exceeds a transformation temperature of the SMA wire. The tightening of the SMA wire causes the plurality of wheels to rotate and induce motion in the volume of fluid and causes the volume of fluid to decrease in temperature.

In further embodiments, the plurality of wheels may remain in motion until the temperature of the volume of fluid is reduced to below the transformation temperature of the SMA wire.

In still further embodiments, the plurality of wheels may include first and second pullies, wherein the first pulley is larger than the second pulley and wherein the second pulley is immersed in the volume of fluid.

In some embodiments, the plurality of wheels may include first and second blades, wherein the first blade is larger than the second blade and wherein the second blade is emersed in the volume of fluid.

In further embodiments, the SMA may include Nitinol.

In still further embodiments, the fluid velocity inside the immersion cooling tank and air speed over an external radiator caused by the SMA heat engine may increase heat transfer capability of the passive cooling system.

In some embodiments, the SMA heat engine may draw power from a temperature differential inside and outside of the immersion cooling tank.

In further embodiments, the SMA heat engine may include flow rates in the immersion cooling tank without addition of external power.

In still further embodiments, the fluid may be thermally conductive and electrically insulating.

In some embodiments, the immersion cooling tank may further include electronic components positioned in the immersion cooling tank and the cooled volume of fluid may cool the electronic components positioned in the immersion cooling tank.

Related heat engines are also provided.

### BRIEF DESCRIPTION OF THE DRAWINGS

FIG. 1A is diagram illustrating an immersion tank including a plurality of fluid cooling channels in accordance with some embodiments of the present inventive concept.

FIG. 1B is a diagram illustrating one of the plurality of fins in accordance with some embodiments of the present inventive concept.

FIG. 2A is a cross-section illustrating an immersion tank including components and coolant and having fins in accordance with some embodiments of the present inventive concept.

FIG. 2B is a perspective view of the system of FIG. 2A illustrating a three dimensional representation of the tank and the elements therein in accordance with some embodiments of the present inventive concept.

FIGS. 3A through 3C are diagrams illustrating a velocity contour diagram, a temperature contour diagram and a velocity vectors diagram, respectively, illustrating aspects of cooling using immersion fluid in accordance with some embodiments of the present inventive concept.

FIG. 4A is a diagram illustrating an immersion tank having hollow channel fluid cooling channels in accordance with some embodiments of the present inventive concept.

FIG. 4B is a cross section of the immersion tank having hallow channels illustrated in FIG. 4A in accordance with some embodiments of the present inventive concept.

FIG. 4C is a perspective view of the cross section of FIG. 4B showing three dimensions of the tank and the elements therein in accordance with some embodiments of the present inventive concept.

FIGS. 5A through 5C are diagrams illustrating a velocity contour diagram, a temperature contour diagram and a velocity vectors diagram, respectively, for embodiments illustrated in FIGS. 4A through 4C in accordance with some embodiments of the present inventive concept.

FIGS. 6A and 6B are diagrams illustrating flat external channels having connecting fins in accordance with some embodiments of the present inventive concept.

FIG. 7 is a diagram illustrating a heat engine in accordance with some embodiments of the present inventive concept.

FIGS. 8 and 9 are diagrams illustrating a passive immersion-cooled system including an SMA heat engine in accordance with some embodiments of the present inventive concept.

FIGS. 10 and 11 are diagrams illustrating alternative embodiments of a passive immersion-cooled system including an SMA heat engine in accordance with some embodiments of the present inventive concept.

### DETAILED DESCRIPTION OF EMBODIMENTS

The inventive concept now will be described more fully hereinafter with reference to the accompanying drawings, in which illustrative embodiments of the inventive concept are shown. This inventive concept may, however, be embodied in many different forms and should not be construed as limited to the embodiments set forth herein; rather, these embodiments are provided so that this disclosure will be thorough and complete, and will fully convey the scope of the inventive concept to those skilled in the art. Like numbers refer to like elements throughout. As used herein, the term “and/or” includes any and all combinations of one or more of the associated listed items. Similarly, as used herein, the word “or” is intended to cover inclusive and exclusive OR conditions. In other words, A or B or C includes any or all of the following alternative combinations as appropriate for a particular usage: A alone; B alone; C alone; A and B only; A and C only; B and C only; and A, B and C.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Reference will now be made in detail in various and alternative example embodiments and to the accompanying figures. Each example embodiment is provided by way of explanation, and not as a limitation. It will be apparent to those skilled in the art that modifications and variations can be made without departing from the scope or spirit of the disclosure and claims. For instance, features illustrated or described as part of one embodiment may be used in connection with another embodiment to yield a still further embodiment. Thus, it is intended that the present disclosure includes modifications and variations that come within the scope of the appended claims and their equivalents.

As discussed above, power conversion equipment and electronic assemblies are often conventionally cooled using fan cooling, which uses forced air delivered by fans to a heat sink to dissipate heat generated by the components. More recently, immersion cooled electronic installations use active elements to cool the fluid, and thereby, the immersed electronics. The immersion fluid is generally pumped through the immersion container, then to a heat exchanger to remove the heat from the fluid. However, the fluid generally must be pumped around and a heat exchanger must be used to remove the heat from the liquid.

Accordingly, some embodiments of the present inventive concept provide a passive fluid cooling apparatus, which cools the immersion fluid without the need for extra equipment such as a heat exchanger. As will be discussed below, embodiments of the present inventive concept take advantage of the fact that when the temperature of the fluid, for example, a dielectric, in the tank increases, the density of the fluid decreases. Thus, the heated fluid rises to the top of the tank and is cooled by circulating the fluid through external tubes (fluid cooling channels). This external arrangement of tubes allows dissipation of heat without use of any fans or pumps which significantly increases power usage effectiveness and efficiency of the immersed electronic assemblies as will be discussed below with respect to the figures.

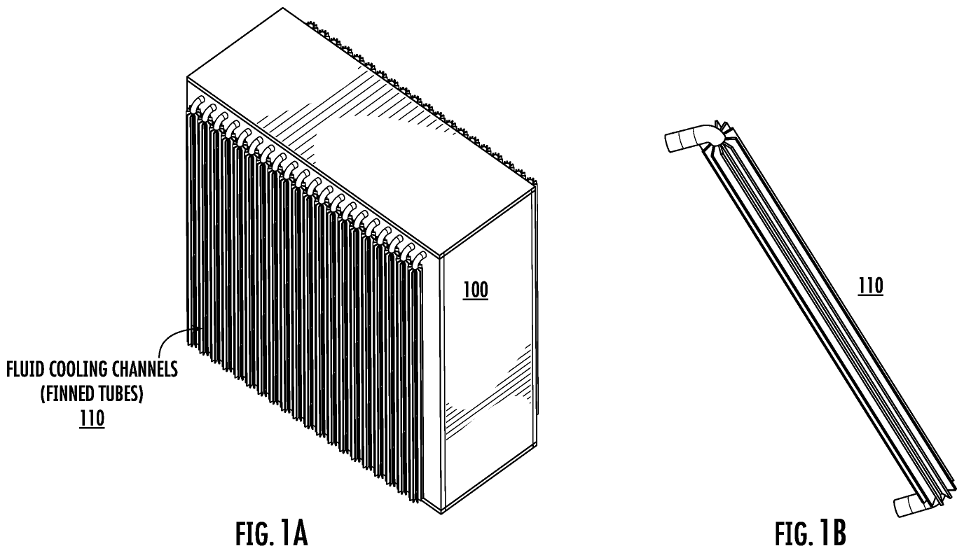

Referring first to FIGS. 1A and 1B, an immersion tank 100 and a plurality of fluid cooling channels 110 in accordance with some embodiments of the present inventive concept will be discussed. As illustrated in FIG. 1A, an immersion tank 100 is provided with a plurality of fluid cooling channels 110 attached thereto. As used herein, “immersion cooling” is an information technology (IT) cooling practice by which IT components and other electronics, including complete servers and storage devices and power equipment, are submerged in a thermally conductive but electrically insulating dielectric liquid or coolant. Conventionally heat is removed from the system by circulating relatively cold liquid into direct contact with hot components, then circulating the now heated liquid through cool heat exchangers. Unlike many other applications, water cooling cannot be used as normal water is electrically conductive and will break electronic components. Fluids suitable for immersion cooling have electrically insulating properties to ensure that they can safely come into contact with energized electronic components.

An immersion cooling tank 100 is a tank in which the electronic components are placed and is filled with a body of dielectric liquid where electronic components are immersed in the dielectric liquid. Thus, various electronic components can share the same liquid. As used herein, the liquid or fluid can include any liquid, fluid, oil or the like that can be safely used to cool electronic equipment. The immersion cooling tanks is fully sealed and can generally be opened from the top to service the IT equipment therein.

Unlike conventional immersion cooling systems, embodiments of the present inventive concept include one or more tubes 110 attached to the tank 100 that allows the fluid in the tank 100 to be circulated such that the fluid is cooled. Embodiments of a finned tube (fluid cooling channel) 110 in accordance with some embodiments of the present inventive concept is illustrated, for example, in FIG. 1B. As illustrated therein, the tube 110 is provided with a plurality of fins attached to the exterior thereof. Embodiments are not limited to the specific number of fins shown FIGS. 1A and 1B. The external arrangement of the tubes 110 on the tank 100 allows dissipation of heat from the liquid without use of any fans or pumps which significantly increases power usage effectiveness and efficiency of the immersed electronic assemblies.

In particular, as illustrated in FIGS. 1A and 1B, the tubes 110 attach at both the top and bottom of the tank 100. When a temperature of the fluid inside the tank, for example, a dielectric, increases, the density of the fluid decreases causing the less dense fluid to rise to the top of the tank 100. The fluid at the top of the tank 100 is filtered/circulated through the tubes 110 from the top of the tank 100 and reenters to the tank 100 at the bottom. The movement of the fluid through the external tubes 110 decreases the temperature of the fluid so that the fluid continues to cool the components positioned in the tank.

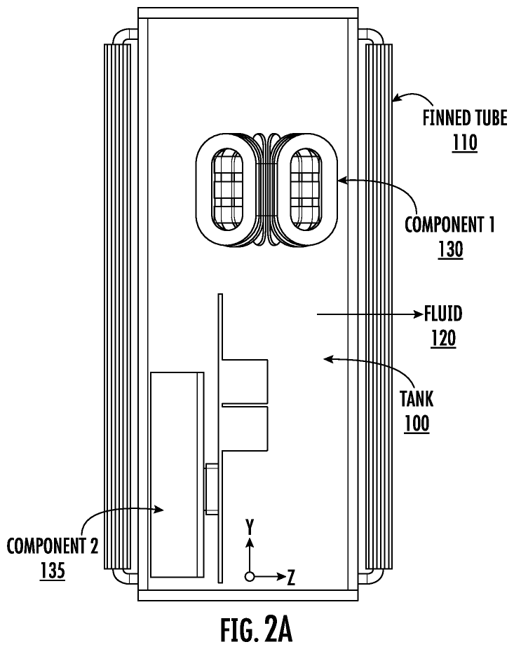

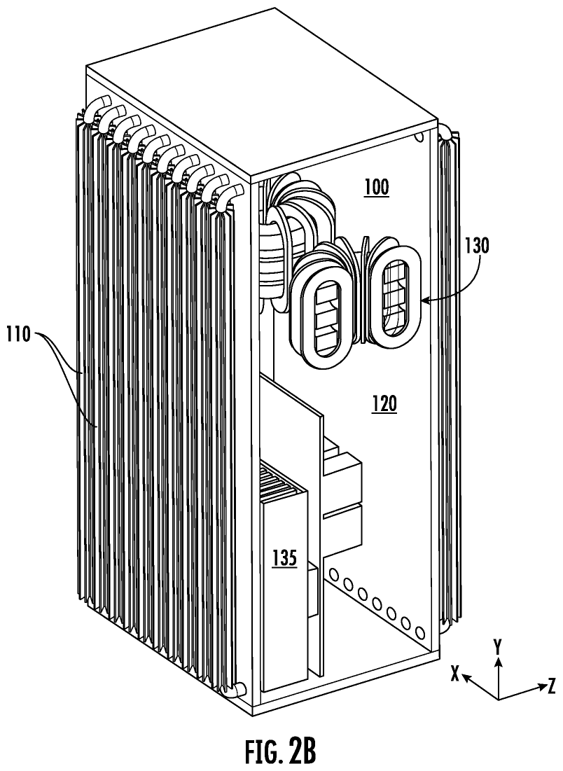

Referring now to FIG. 2A, as illustrated in the cross-section of the tank 100, component(s) 130 and 135 are submerged in a coolant/fluid 120, for example, a dielectric liquid. As used herein, “components” refer to any electrical components that may generate heat that are customarily cooled in a traditional manner. For example, components discussed herein may include uninterruptable power supplies (UPSs), for example, single and three phase UPSs, motor drives, or any other power conversion equipment. Although FIG. 2A only illustrates two components 130 and 135 in the tank 100, embodiments of the present inventive concept are not limited to this configuration. A single component or more than two components may be positioned in the tank 100 without departing from the scope of the present inventive concept.

The heat associated with the component(s) 130 and 135 is transferred to the surrounding dielectric liquid (coolant 120). The temperatures used in immersion cooling are determined by the highest temperature at which the devices being immersed can reliably operate. For servers this temperature may range between 15 to 65° C. (59 to 149° F.), but may be extended up to 75° C. The transfer of heat to the coolant increases a temperature of coolant 120 near the component(s) 120, which results in a decrease in density of the coolant 120. The coolant 120 rises due to the resulting buoyancy force. The coolant 120 rising in the tank induces a circulating flow through the external tubes 110. The heat in the fluid is transferred to the surrounding air aided by the fins (FIG. 1B) which serve to increase the area available for heat transfer.

FIG. 2B is a perspective view of the cross section of the tank 100 of FIG. 2A. FIG. 2B illustrates x, y and z dimensions of the tank 100. Thus, the positioning of the components and other elements are more accurately depicted.

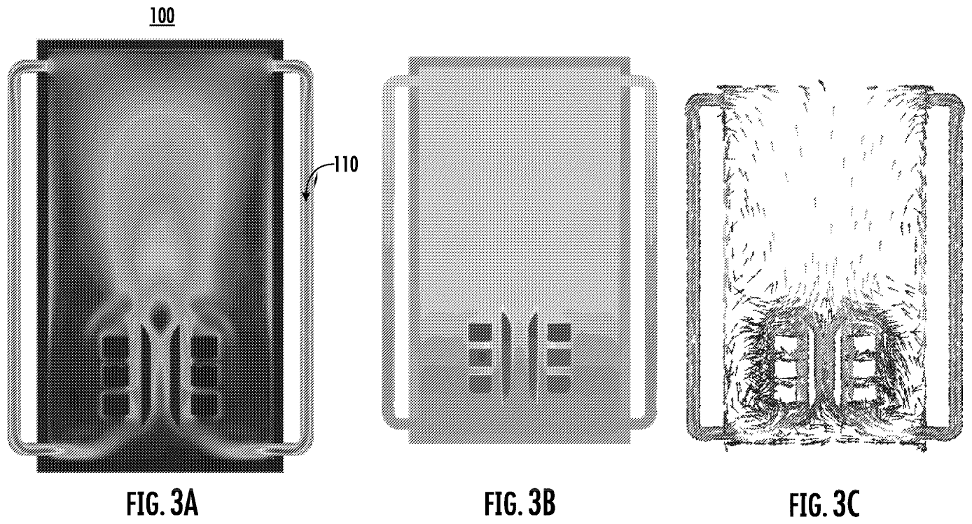

FIGS. 3A through 3C are a velocity contour diagram, a temperature contour diagram and a velocity vectors diagram, respectively, illustrating aspects of the present inventive concept. The vectors of FIG. 3C illustrate the induced circulating flow within the tank and through the tubes.

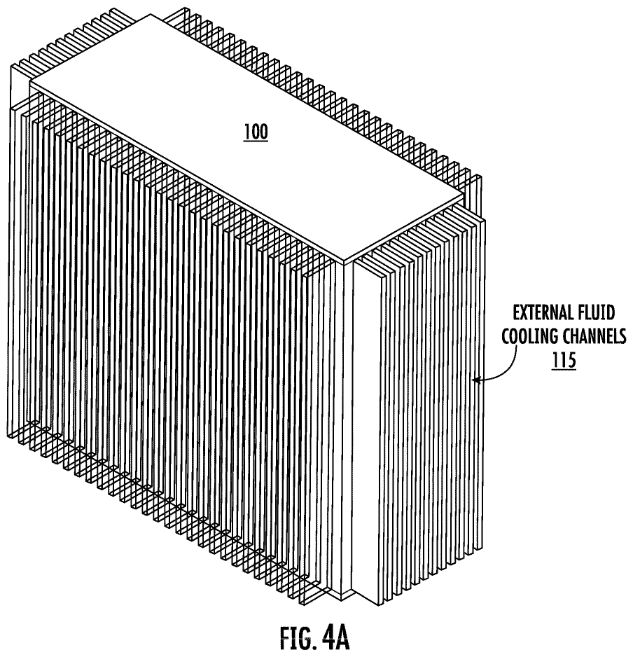

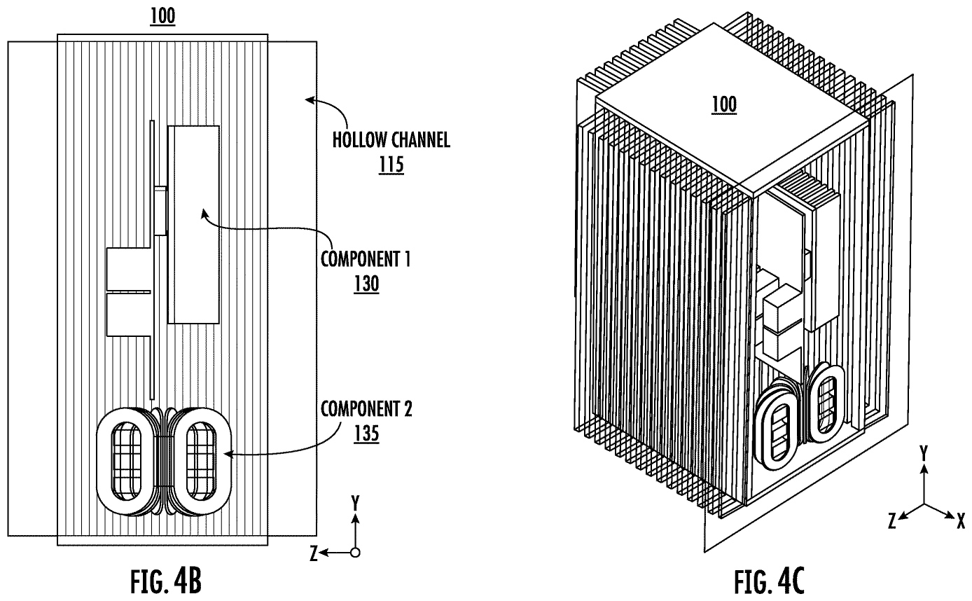

Although the fluid cooling channels 110 are shown having a finned configuration in FIGS. 1A through 2B, embodiments of the present inventive concept are not limited to this configuration. For example, any type or shape may be used for the fluid cooling channels without departing from the scope of the present inventive concept. Thus, any embodiment where one or more cooling channels are attached to an immersion tank may be used. The fluid cooling channels may be, for example, radial discs with holes, fractal designs, and the like. Furthermore, fluid cooling channels can have one or a combination of several cross-sections: round, rectangular, racetrack, etc. Examples of various embodiments of fluid cooling channels are illustrated in FIGS. 4A through 4C. Embodiments are not limited to those shown in these figures and these figures are provided for example only.

Referring in particular to FIGS. 4A through 4C illustrating hollow channel embodiments for the fluid cooling channel in accordance with some embodiments of the present inventive concept. As illustrated in FIG. 4A, external flat channels 115 are formed into or attached to the side of tank 100. In these embodiments, passages inside the flat channels 156 conduct the fluid to exhaust the heat to the surrounding air. The circulatory flow in the tank 100 and external channels 115 is the same or similar as in the tank and tubes as discussed above.

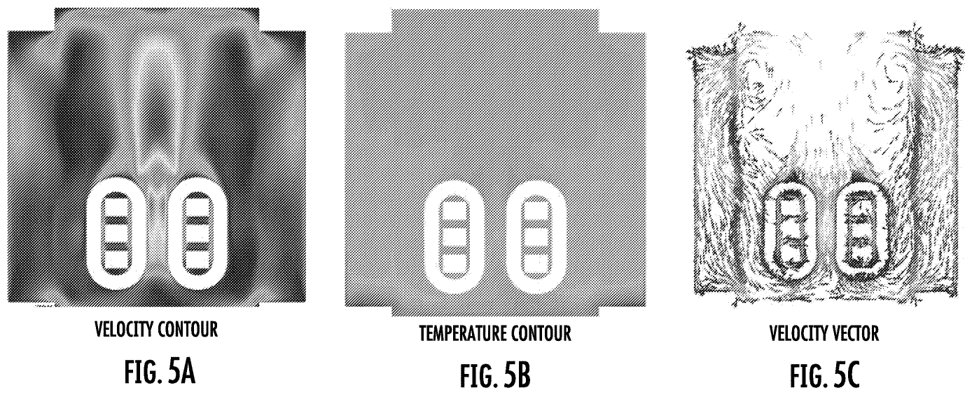

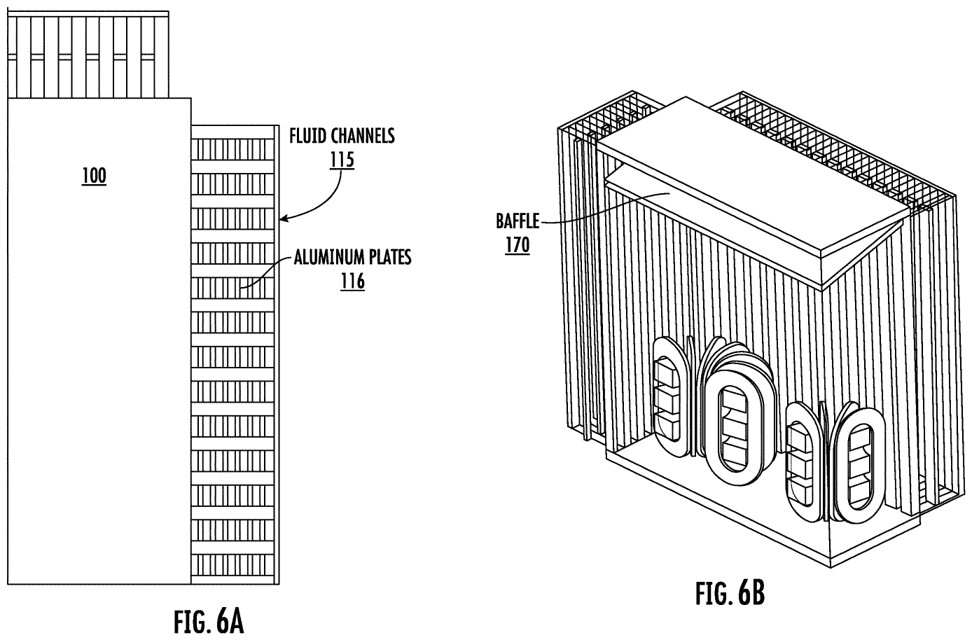

FIGS. 5A through 5C are diagrams illustrating a velocity contour diagram, a temperature contour diagram and a velocity vectors diagram, respectively, for embodiments illustrated in FIGS. 4A through 4C in accordance with some embodiments of the present inventive concept.

FIGS. 6A and 6B are a diagram and perspective cross section, respectively, of embodiments including flat channels and connections fins. As illustrated in FIG. 6A, the flat channels 115 have interconnecting fins 116 (aluminum plates) to increase surface area in order to augment heat transfer as shown in FIGS. 3A-3C and FIGS. 5A through 5C. Furthermore, FIG. 6B illustrates a baffle 170 for replacing fluid or removing/adding components.

In some embodiments, the tank itself may be made to include features that guide the less dense fluid into the fluid cooling channels as discussed herein. For example, in some embodiments, a portion of the top of the tank may angle downward to facilitate entry of the fluid into the fluid cooling channels. Furthermore, additional features, such as baffles, can be installed inside the tank 100 to help direct the flow of the heated coolant 120 to augment effectiveness of the tank 100. These baffles can be an integral part of the tank 100 structure or installed separately. These baffles can be custom configured depending on what components or equipment are being cooled. The installed equipment can also have individual features that assist in directing the coolant 120 to increased cooling effectiveness.

As discussed above, conventional immersion cooled electronic installations use active elements to cool the fluid, and thereby, the immersed electronics. The immersion fluid is generally pumped through the immersion container (tank), then to a heat exchanger to remove the heat from the fluid. Embodiments of the present inventive concept provide a passive fluid cooling apparatus which reduces the power consumption of immersion cooled equipment and expands possible installation location options for the IT equipment.

In particular, immersion cooling reduces energy consumption through the elimination of the air cooling infrastructure including on-board server fans, CRACs, A/C compressors, air-circulation fans, necessary duct work, air handlers, and other active ancillary systems such as dehumidifiers. As discussed above, embodiments of the present inventive concept replace these conventional systems with liquid immersion techniques having passive cooling systems for the fluid in the tanks. Thus, embodiments of the present inventive concept do not require fans to circulate the dielectric liquid nor heat exchangers to cool the liquid.

As discussed above with respect to FIGS. 1 through 6A, in passive immersion cooling, electronic or other heat generating components are immersed in a dielectric fluid coolant. The components heat the fluid during operation and this heat induces a flow in the immersion container (tank). In some embodiments, this induced flow circulates the hot fluid through an external radiator where it releases heat to the atmosphere as shown, for example, in FIG. 2A. However, as the motion of both coolant and air are by natural circulation, the amount of heat this apparatus can remove may be limited by the naturally induced flow inside the tank.

Accordingly, some embodiments of the present inventive concept use shape-memory alloys (SMA) to create a fluid mover that draws power from a temperature differential and requires no external power source to operate. Thus, these embodiments induce flow rates in passive immersion-cooled systems that generally have high temperature gradients due to local heating from cooled components and relatively low induced flow rates. Use of SMA fluid mover as discussed herein augments the coolant flow in the container and, thereby, increasing the system's capacity and performance as will be discussed further below with respect to FIGS. 8 through 11.

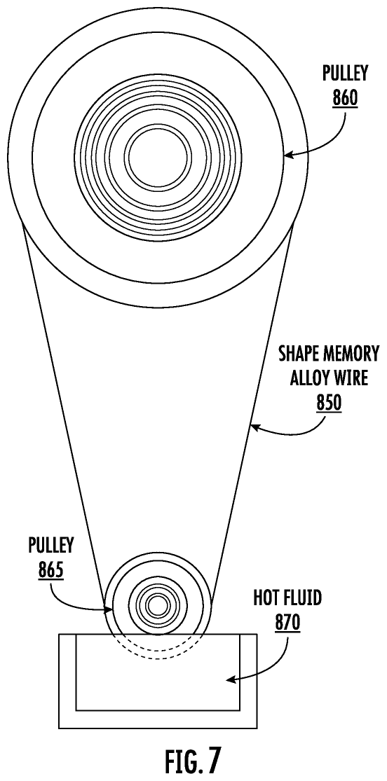

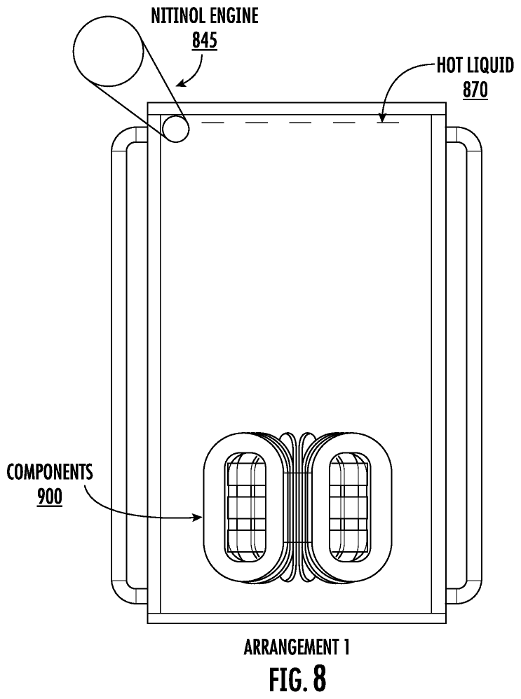

As discussed above, passive immersion-cooled systems generally include a passive immersion tank 100 including fluid 120, for example, dielectric fluid, that takes up heat from electronic components 120, 130 and dissipates it to outside ambient due to buoyancy driven circulation created inside the tank. In accordance with embodiments discussed herein, a fluid mover may be used to further stimulate motion of the fluid. For example, FIG. 7 illustrates an SMA heat engine in accordance with some embodiments of the present inventive concept.

An SMA, for example, Nitinol, heat engine 845 is illustrated in FIG. 7. Nitinol is a metal alloy that can “remember” or change shape based on temperature. As illustrated, a loop of, for example, Nitinol wire, 850 is placed over first 860 and second 865 pullies/wheels. The wheels 860, 865 are free to rotate. The applicable property of a SMA wire is its change of shape, i.e. to straighten out, when heated above a transformation temperature. In particular, the wire 850 transforms from a relaxed state to a tightened state when the wire 850 is heated. The smaller wheel 865 of this engine 845 is dipped in the hot fluid 870 (immersion fluid) which is hotter than the transformation temperature of the SMA wire 850 while the larger wheel 865 is outside the water (tank) in air that is below the transformation temperature. Thus, this configuration will cause the wheels 860, 865 of the engine to spin. The wheels of the engine will rotate as long as the liquid 870 is above transformation temperature of the SMA and the air is below the temperature of the SMA. FIG. 7 illustrates the wire 850 in a tightened position.

It will be understood that the wire 850 is discussed herein as being a nitinol wire, however, embodiments of the present inventive concept are not limited thereto. For example, the wire 850 may be any type of SMA without departing from the scope of the present inventive concept.

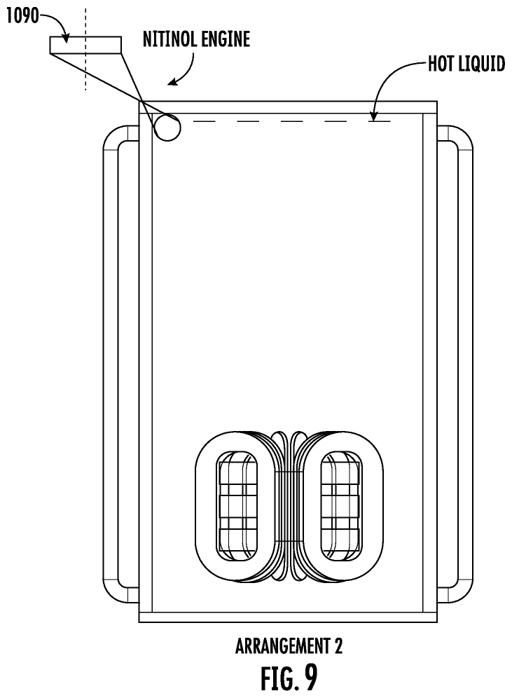

FIG. 8 illustrates a passive immersion-cooled system including the heat engine 845 of FIG. 7. The SMA heat engine 845 is used to move the fluid 870 so that the fluid 870 heated by the components 900 can be more rapidly cooled. FIG. 9 illustrates an embodiment where blades 1090 are attached to the SMA engine to provide a pumping action inside the tank and air flow over the external radiator. As illustrated, the blade 1090 can move up and down as indicated by the dotted line. However, it will be understood that embodiments of the present inventive concept are not limited to this configuration.

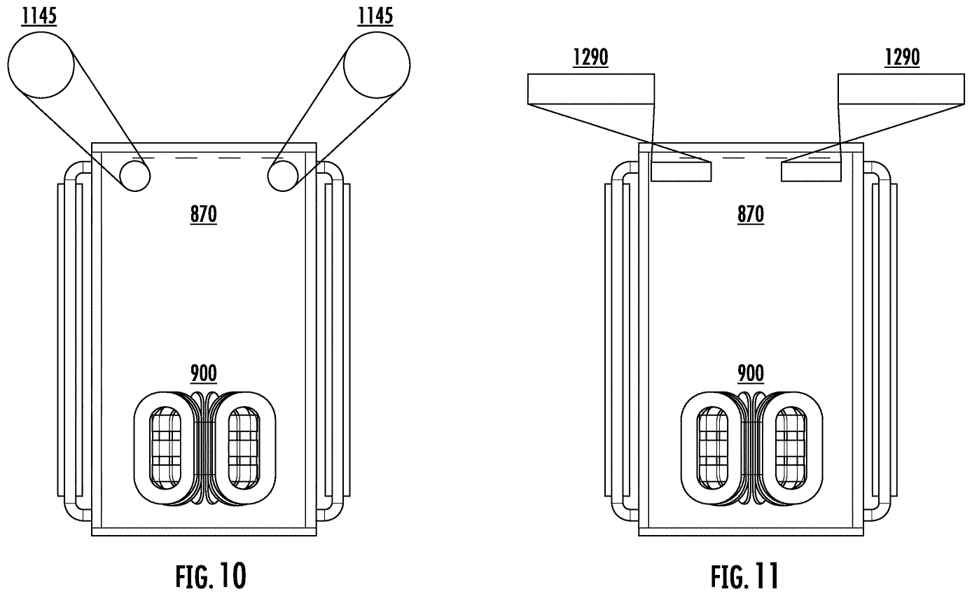

Furthermore, although FIGS. 8 and 9 illustrate positioning of the engine 845/1090 at an upper corner of the tank, embodiments of the present inventive concept are not limited thereto. For example, as shown in FIGS. 10 and 11, the engines 1145/1290 may be positioned in different locations and there may be more than one engine 1145/1290 without departing from the scope of the present inventive concept.

The increase in fluid velocity inside the tank and air speed over the external radiator caused by the SMA engine in accordance with embodiments discussed herein increases the heat transfer capability of the immersion cooling system. These advantages may be achieved without the addition of external power.

As discussed briefly herein, some embodiments of the present inventive concept improve functionality of a passive immersion-cooled system using a shape-memory alloy (SMA) engine to provide pumping action inside the tank. The SMA engine may be driven by the heat dissipated by the components in the tank as discussed above. In the drawings and specification, there have been disclosed exemplary embodiments of the inventive subject matter. Although specific terms are employed, they are used in a generic and descriptive sense only and not for purposes of limitation, the scope of the inventive subject matter being defined by the following claims.

What is claimed is:

1. A passive fluid cooling system, comprising:
an immersion cooling tank including a volume of fluid; and
a shape memory alloy (SMA) heat engine, the SMA heat engine including a plurality of wheels and an SMA wire coupled to the plurality of wheels,
wherein a portion of the SMA wire is in contact with the volume of fluid and transitions from a relaxed state to a tightened state when a temperature of the volume of fluid exceeds a transformation temperature of the SMA wire; and
wherein tightening of the SMA wire causes the plurality of wheels to rotate and induce motion in the volume of fluid and causes the volume of fluid to decrease in temperature.

2. The system of claim 1, wherein the plurality of wheels remain in motion until the temperature of the volume of fluid is reduced to below the transformation temperature of the SMA wire.

3. The system of claim 1, wherein the plurality of wheels comprises first and second pullies, wherein the first pulley is larger than the second pulley and wherein the second pulley is immersed in the volume of fluid.

4. The system of claim 1, wherein the plurality of wheels comprise first and second blades, wherein the first blade is larger than the second blade and wherein the second blade is immersed in the volume of fluid.

5. The system of claim 1, wherein the SMA comprises Nitinol.

6. The system of claim 1, wherein fluid velocity inside the immersion cooling tank and air speed over an external radiator caused by the SMA heat engine increases heat transfer capability of the passive cooling system.

7. The system of claim 1, wherein the SMA heat engine draws power from a temperature differential inside and outside of the immersion cooling tank.

8. The system of claim 1, wherein the SMA heat engine induces flow rates in the immersion cooling tank without addition of external power.

9. The system of claim 1, wherein the fluid is thermally conductive and electrically insulating.

10. The system of claim 1, wherein the immersion cooling tank further includes electronic components positioned in the immersion cooling tank and wherein the cooled volume of fluid cools the electronic components positioned in the immersion cooling tank.

11. A shape memory alloy (SMA) heat engine for use with a passive cooling system, the SMA heat engine comprising:
a plurality of wheels and an SMA wire coupled to the plurality of wheels,
wherein a portion of the SMA wire is in contact with a volume of fluid and transitions from a relaxed state to a tightened state when a temperature of the volume of fluid exceeds a transformation temperature of the SMA wire; and
wherein tightening of the SMA wire causes the plurality of wheels to rotate and induce motion in the volume of fluid and causes the volume of fluid to decrease in temperature.

12. The engine of claim 11, wherein the plurality of wheels remain in motion until the temperature of the volume of fluid is reduced to below the transformation temperature of the SMA wire.

13. The engine of claim 11, wherein the plurality of wheels comprises first and second pullies, wherein the first pulley is larger than the second pulley and wherein the second pulley is immersed in the volume of fluid.

14. The engine of claim 11, wherein the plurality of wheels comprise first and second blades, wherein the first blade is larger than the second blade and wherein the second blade is immersed in the volume of fluid.

15. The engine of claim 11, wherein the SMA comprises Nitinol.

16. The engine of claim 11, wherein fluid velocity inside an immersion cooling tank and air speed over an external radiator caused by the SMA heat engine increases heat transfer capability of the passive cooling system.

17. The engine of claim 11, wherein the SMA heat engine draws power from a temperature differential inside and outside of an immersion cooling tank.

18. The engine of claim 11, wherein the SMA heat engine induces flow rates in the immersion cooling tank without addition of external power.

19. The engine of claim 11, wherein the fluid is thermally conductive and electrically insulating.

20. The engine of claim 11, wherein the immersion cooling tank further includes electronic components positioned in an immersion cooling tank and wherein the cooled volume of fluid cools the electronic components positioned in the immersion cooling tank.
